(19) United States
(12) Patent Application Publication
(10) Pub. No.: US 2022/0268828 A1
(43) Pub. Date: Aug. 25, 2022

(54) ARC DETECTION METHOD AND ARC DETECTION SYSTEM

(71) Applicant: PSK INC., Hwaseong-si (KR)

(72) Inventors: HEE-WOONG SHIN, Hwaseong-si (KR); HYEONG-SHIN CHO, Hwaseong-si (KR)

(21) Appl. No.: 17/206,379

(22) Filed: Mar. 19, 2021

(30) Foreign Application Priority Data
Feb. 24, 2021 (KR) 10-2021-0024479

(51) Int. Cl. G01R 31/26

(52) U.S. Cl. CPC G01R 31/2601

(57) ABSTRACT

Disclosed herein is a method of detecting an arc generated in a semiconductor device. The method may comprise: performing a processing process for a substrate processing and collecting data according to the processing process; separating the collected data by setting sections; obtaining an average value and a standard deviation of the data separated for each section; and setting an upper limit and a lower limit for detecting the arc using the average value and the standard deviation.

### FIELD OF THE INVENTION

The present disclosure relates to an arc detection method and arc detection system.

A claim for priority under 35 U.S.C. § 119 is made to Korean Patent Application No. 10-2021-0024479 filed on Feb. 24, 2021, in the Korean Intellectual Property Office, the entire contents of which are hereby incorporated by reference.

### BACKGROUND

The present disclosure relates to an arc detection method and an arc detection system. More specifically, the present disclosure relates to a method and system capable of detecting an arc using an average value and a standard deviation.

Usually, a semiconductor device is fabricated by forming various films on a semiconductor substrate, for example a silicon substrate and patterning the films. The manufacturing of the semiconductor device includes various unit processes such as chemical vapor deposition, sputtering, photolithography, etching, ion implantation, chemical mechanical polishing (CMP), cleaning, and the like.

Among the unit processes hereinabove, the etching process is mainly performed by dry etching, and the dry etching uses plasma generated from reaction gases in a process chamber to remove predetermined portions of a film on a substrate via chemical reaction with the film. The substate to be processed in the process chamber is fixedly supported by a substate supporter. The substrate supporter includes, for example, an electro static chuck (ESC) for adsorbing and supporting the substrate by electrostatic force, or a vacuum chuck for adsorbing and supporting the substrate by vacuum pressure.

A polymer unnecessarily attached to the rear surface of the substrate loaded into the process chamber may not be completely removed and fall into the process chamber during the loading/unloading of the substrate, thereby generating by reacting with plasma. Besides, an arc may occur for other reasons.

Previously, in order to detect the arc, a box was used or a method of detecting the arc by simply tracking only the slope was used.

FIGS. 1 to 2 are views for explaining an arc detection method according to a conventional method.

Referring to FIGS. 1 to 2, a problem with the known art is that it is difficult to detect an arc with an absolute value or an absolute slope value of a parameter due to the change of the level of noise and the change of the average intensity during the process.

That is, a problem with the conventional arc detection method is that it is difficult to easily distinguish between an arc signal and a noise signal, and has low data quality because it was detected only with absolute values or slopes. In the case of using a conventional high-resolution arc detector, the time interval is very small (several ns˜several μs) even if the noise is small and thus when the arc is detected with a slope angle, it was difficult to distinguish between arc and noise because the arc signal itself was divided into several points. In order to overcome this, when a high-resolution detector is installed, a large number of noises are generated. Although the development and commercialization of high-resolution arc detectors have already been made, unfortunately, the detection algorithm does not keep up with the advanced detection method. For example, the algorithms still adopt convention method of measuring only slope parameters or using a box algorithm.

Another problem with the known art is that the accuracy is low in detecting the arc with the absolute value and the absolute slope value of the parameter since the parameters react sensitively according to the type of film deposited on the substrate and the processing recipe.

### SUMMARY

The present disclosure is directed to providing an algorithm that can easily detect an arc even at high resolution.

The problem to be solved by the present invention is not limited to the problem mentioned above. Other technical problems not mentioned will be clearly understood by those of ordinary skilled in the art from the following description.

An exemplary embodiment of the present disclosure provides a method of detecting an arc generated in a semiconductor device.

A method of detecting an arc generated in a semiconductor device may comprise: performing a processing process for a substrate processing and collecting data according to the processing process; separating the collected data by setting sections; obtaining an average value and a standard deviation of the data separated for each section; and setting an upper limit and a lower limit for detecting the arc using the average value and the standard deviation.

In an embodiment, the separating the collected data by setting sections may separate the collected data except for data immediately after the start of the process and immediately before the end of the process.

In an embodiment, the setting an upper limit and a lower limit for the arc detection using the average value and the standard deviation may set a value by adding n multiplied by any number of the standard deviation to the average value as an upper limit and may set a value by subtracting n multiplied by any number of the standard deviation from the average value as the lower limit.

In an embodiment, the separating the collected data by setting sections may comprise separating the collected data by setting sections based on the number of data.

In an embodiment, when a detected signal exceeds the upper and lower limits, it is determined that an arc has occurred.

In an embodiment, the setting an upper limit and a lower limit for the arc detection using the average value and the standard deviation may set the upper and lower limits differently for each parameter or recipe in the processing process.

In an embodiment, a computer-readable recording medium may be disclosed in which a program for executing the arc detection method is recorded.

Another exemplary embodiment of the present disclosure provides a system capable of detecting an arc generated in a semiconductor device.

The system may comprise: a data collection unit for collecting a result of processing a substrate for processing a substrate in the semiconductor device; and an arc detection unit for detecting the arc using an average value and a standard deviation for each section based on the data collected by the data collection unit.

In an embodiment, the arc detection unit may comprise a data separation unit for separating the data collected by the data collection unit for each section; a calculation unit for calculating an average value and a standard deviation of the data separated for each section in the data separation unit; a reference setting unit for setting an upper limit and a lower limit for arc detection by applying a value calculated by the calculation unit; and a determination unit for determining that an arc has occurred when an arc signal exceeds the reference value set by the reference setting unit.

In an embodiment, the data separation unit may separate the collected data except for data immediately after the start of the process and immediately before the end of the process.

In an embodiment, the reference setting unit may set an upper limit by adding n multiplied by any number of the standard deviation to the average value, and may set a lower limit by subtracting an n multiplied by any number of the standard deviation from the average value.

In an embodiment, the reference setting unit may set an upper limit and a lower limit differently for each parameter or recipe in the processing process.

Another exemplary embodiment of the present disclosure provides an arc detection system comprising a processor and a memory storing program code executable by the processor.

The processor may execute: performing a processing process for a substrate processing and collecting data according to the processing process; separating the collected data by setting sections; obtaining an average value and a standard deviation of the data separated for each section; and setting an upper limit and a lower limit for detecting an arc using the average value and the standard deviation.

According to the present disclosure, it is possible to easily detect the arc compared to the conventional method.

The effects of the present disclosure are not limited to the aforementioned effects. Effects not mentioned herein will be clearly understood by those having ordinary skill in the art from the present specification and the accompanying drawings.

### BRIEF DESCRIPTION OF THE FIGURES

FIGS. 1 to 2 are views for explaining an arc detection method according to a conventional method.

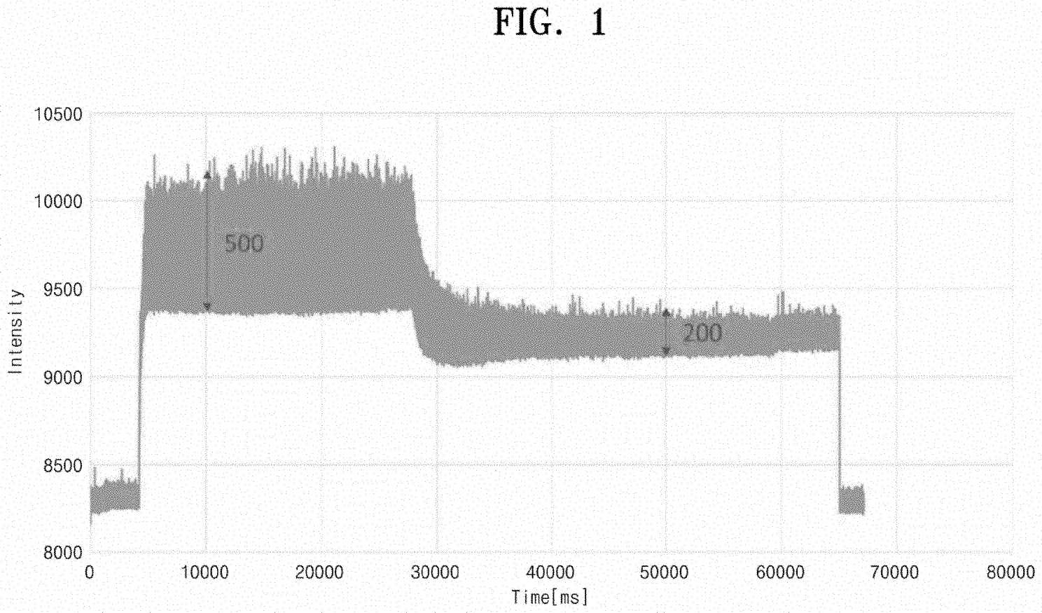

FIG. 3 is a block diagram showing the configuration of an arc detection system according to an embodiment of the present disclosure.

FIG. 4 is a block diagram showing the configuration of an arc detection unit according to an embodiment of the present disclosure.

FIG. 5 is a block diagram showing the configuration of an arc detection system according to another embodiment of the present disclosure.

FIG. 6 is a view showing an embodiment of setting an upper limit and a lower limit for arc detection according to an embodiment of the present disclosure.

FIG. 7 is a view showing an embodiment of setting an upper limit and a lower limit under various conditions.

FIG. 8 is a view showing performing arc detection according to an embodiment of the present disclosure.

FIG. 9 is a view for explaining a section setting in data.

FIG. 10 is a view for explaining an arc detection method according to an embodiment of the present disclosure.

### DETAILED DESCRIPTION

Hereinafter, embodiments of the present disclosure will be described in more detail with reference to the accompanying drawings so that those with average knowledge in the art could easily carry out the present disclosure. The embodiments of the present disclosure may be modified in various forms, and the scope of the present disclosure should not be construed as being limited to the following embodiments. Additionally, in a preferred embodiment of the present disclosure, when it is deemed that a detailed description of known functions or configurations may unnecessarily obscure the subject matter of the present disclosure, the detailed description thereof will be omitted. Throughout the drawings, the same reference numerals are used to refer to the same or like parts.

Whenever appropriate, the terms “comprise” or “comprising” means that other components may be further included rather other components are excluded unless stated explicitly to the contrary herein. More specifically, the terms “comprise”, “have” or “include” etc. are intended to indicate that there is a feature, number, step, action, component, part, or combination thereof described on the specification. It is to be understood that the present disclosure does not exclude the possibility of the presence or the addition of one or more other features or numbers, steps, operations, components, parts or a combination thereof.

Terms such as first or second may be used to describe various components, but the components should not be limited by the terms. The terms are used only for the purpose of distinguishing one component from another, for example without departing from the scope of the rights according to the inventive concept, and the first component may be referred to as a second component and similarly the second component may also be referred to as the first component.

Singular expressions include plural expressions unless the context clearly indicates otherwise. Accordingly, the shapes, sizes, etc. of elements in the drawings may be exaggerated to make the description clear.

‘A˜unit’ and ‘A˜module’ used throughout this specification are units that process at least one function or operation, and may mean, for example, software or hardware components such as FPGA, or ASIC. But ‘A˜unit’ and ‘A˜module’ are not meant to be limited to software or hardware. ‘A˜unit’ and ‘A˜module’ may be configured to be in an addressable storage medium, or may be configured to reproduce one or more processors.

In one example, ‘A˜unit’ and ‘A˜module’ are components including components such as software components, object-oriented software components, class components and task components and processes, functions, properties, procedures, subroutines, segments of program code, drivers, firmware, microcode, circuits, data, databases, data structures, tables, arrays, and variables. Components and functions provided by ‘A unit’ and ‘A˜module’ may be performed separately by a plurality of elements and ‘A˜unit’ and ‘A˜module’, or alternatively, may be integrated with other additional components.

The present disclosure is directed to provide an algorithm for detecting an arc in a semiconductor device using parameters sensitive to arcing during a semiconductor manufacturing process. There are the following problems with the known art: a low accuracy in detecting the arc because of tracking only the slope by tracking the difference between the current value and the previous value of the parameter, or because of tracking the value outside a fixed box (the x-axis is time and the y-axis is the difference in intensity); and a difficulty in distinguishing noises and arc. In the present disclosure, values may be compared in real time by setting an upper limit and a lower limit of data using the average value and multiples of standard deviation within the box. In the present disclosure, given the fact that the arc signal has an abnormally high or low parameter value, the algorithm outputs an arc signal when a detected signal exceeds the set upper or lower limit. It is inappropriate to determine an upper limit and a lower limit without considering other factors because the intensity varies depending on the condition. Accordingly, in the present disclosure, an upper limit and a lower limit are calculated using the average value and standard deviation for parameter and each section. When a detected signal exceeds the upper and lower limits, it is considered to have an arc detected, thereby enabling more accurate arc detection than before.

Hereinafter, an arc detection method and system according to the present disclosure will be described in detail with reference to the drawings.

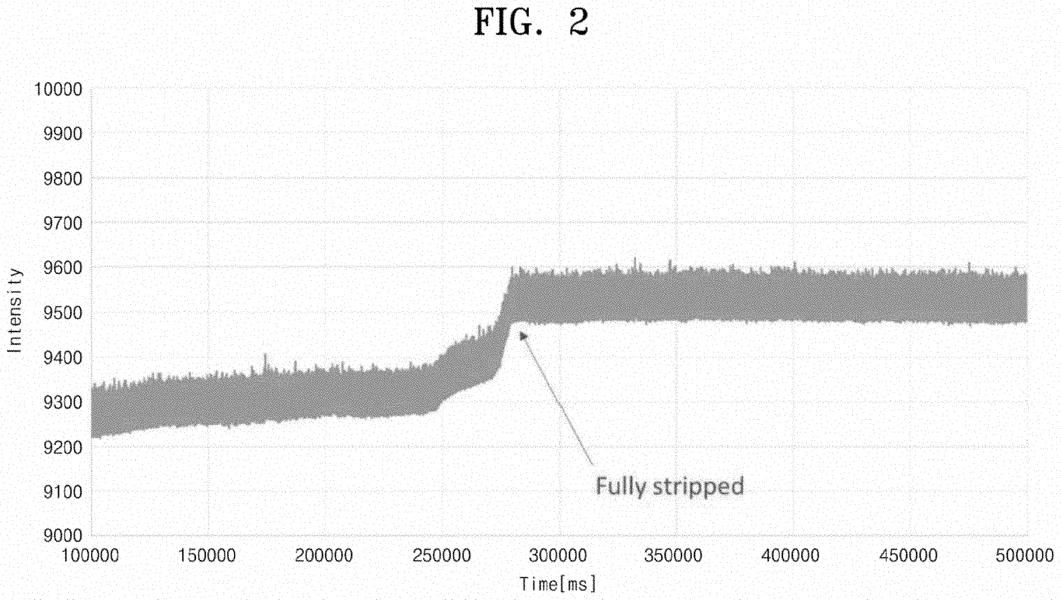

FIG. 3 is a block diagram showing the configuration of an arc detection system according to an embodiment of the present disclosure.

The arc detection system according to an embodiment of the present disclosure may comprise a data collection unit 100 and an arc detection unit 200.

The data collection unit 100 may collect a process result for processing a substrate during a semiconductor manufacturing process. The data collection unit 100 may collect intensity information according to a change in time. The data collection unit 100 may collect a voltage value or a current value according to a process result. The information collected by the data collection unit 100 is not limited thereto, and may be parameter information related to the occurrence of an arc. In an embodiment, the data collected by the data collection unit 100 is intensity.

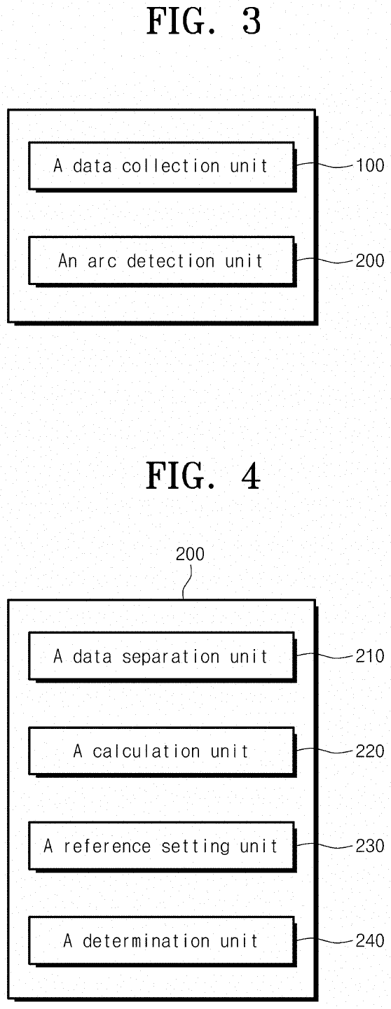

The arc detection unit 200 may detect an arc using an average value and a standard deviation for each section of data collected by the data collection unit 100. A specific configuration of the arc detection unit 200 will be described hereinafter with reference to FIG. 4.

FIG. 4 is a block diagram showing the configuration of an arc detection unit 200 according to an embodiment of the present disclosure.

Referring to FIG. 4, the arc detection unit 200 according to the present disclosure may comprise a data separation unit 210, a calculation unit 220, a reference setting unit 230, and a determination unit 240.

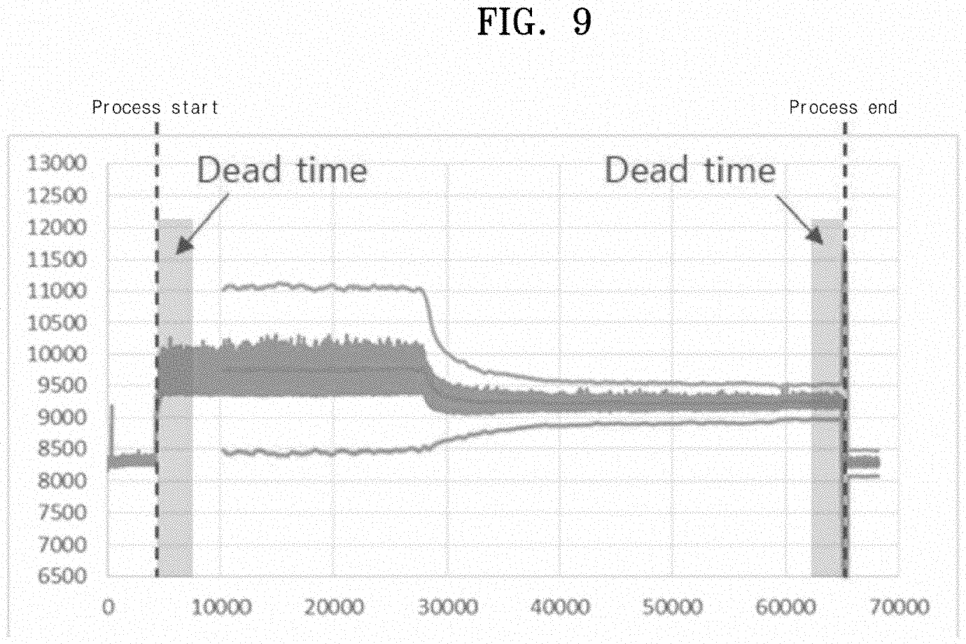

The data separation unit 210 may separate the data collected by the data collection unit 100 for each section. In an embodiment, a reference for separating data by section by the data separation unit 210 may be the number of data. In an embodiment, data may be sequentially classified based on 100 units. In an embodiment, data may be sequentially classified based on 1000 units. In an embodiment, the data separation unit 210 may define classified data as a box. In an embodiment, the data separation unit 210 may sequentially separate the collected data except for data immediately after the start of the process and immediately before the end of the process, which will be described later with reference to FIG. 9.

The calculation unit 220 may calculate an average value and a standard deviation of the data separated for each section in the data separation unit 210. In an embodiment, the calculation unit 220 may calculate an average value and a standard deviation of data for each box. In another embodiment, the calculator 220 may calculate an average value and a standard deviation of data for each box, and may calculate a multiple of the standard deviation.

The reference setting unit 230 may set an upper limit and a lower limit for arc detection by applying a value calculated by the calculation unit 220. The reference setting unit 230 may set an upper limit and a lower limit for arc detection for each box. The reference setting unit 230 may set a value by adding n multiplied by any number of the standard deviation to the average value calculated in the box as an upper limit, and set a value by subtracting n multiplied by any number of the standard deviation from the average value as a lower limit. In this case, n may be an integer. The reference setting unit 230 may set different standards for setting the upper and lower limits, respectively, according to a recipe controlled in a processing process. In an embodiment, suppose there are a first recipe, a second recipe, and a third recipe. When setting an upper limit and a lower limit according to the first recipe, the upper limit may be set by adding one multiple of the standard deviation to the average value. And, the lower limit may be set by subtracting one multiple of the standard deviation from the average value. In another embodiment, when setting an upper limit and a lower limit according to the second recipe, the upper limit may be set by adding two times the standard deviation to the average value, and the lower limit may be set by subtracting two times the standard deviation from the average value. In another embodiment, when setting the upper and lower limit according to the third recipe, the upper limit may be set by adding 3 times the standard deviation to the average value, and the lower limit may be set by subtracting 3 times the standard deviation from the average value. That is, the reference setting unit 230 may set the upper and lower limits with different references according to each condition.

In an embodiment, the reference setting unit 230 may differently set reference for setting an upper limit and a lower limit according to the type of parameter to be measured. In another embodiment, the reference setting unit 230 may differently set a reference for setting the upper and lower limits, respectively, depending on the type of film or the time at which the process proceeds. At this time, the reference to be set may be determined experimentally and empirically. If the multiple is too small, there is a risk of noise, and if the multiple is too large, there is a risk that it may not be detected when an arc occurs. Accordingly, an appropriate multiple value can be set through an experiment.

The determination unit 240 may determine that an arc has occurred when a detected signal exceeds the reference value set by the reference setting unit 230. When data exceeds the upper and lower limits set by the reference setting unit 230, the determination unit 240 may determine that an arc has occurred.

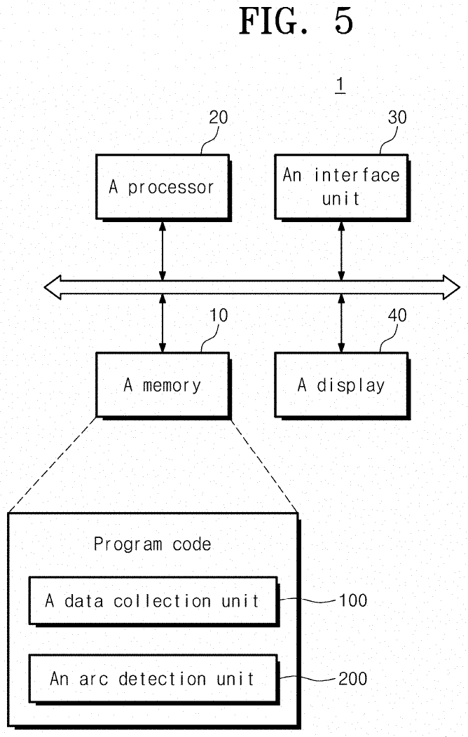

FIG. 5 is a block diagram of an arc detection system capable of arc detection according to an exemplary embodiment of the present invention.

The arc detection method described hereinafter may be performed by a computing device. The computing device comprises at least one of a computer, a workstation, a server, a desktop PC, a netbook, a smartphone, a tablet PC, a mobile phone, a video phone, an e-book reader, a PDA, a PMP, an MP3 player, a medical device, an electronic device, and a wearable device. Additionally, the computing device may be implemented as a centrally managed data storage environment or a distributed data storage environment.

FIG. 5 may be an exemplary computing device or non-transitory computer-readable medium for performing an arc detection method.

Referring to FIG. 5, an arc detection system according to an embodiment of the present disclosure may comprise a memory 10, a processor 20, a display 30, an interface unit 40, and a bus.

Via the bus, various components such as the memory 10, the processor 20, the display 30, and the interface unit 40 may be connected and communicated with each other (i.e., control message transfer and data transfer).

The memory 10 comprises volatile memory (For example, DRAM, SRAM, or SDRAM) and/or non-volatile memory (For example, one-time programmable ROM (OTPROM), PROM, EPROM, EEPROM, mask ROM, flash ROM, flash memory, PRAM, RRAM, MRAM, hard drive, or solid-state drive (SSD)). The memory 10 may comprise an internal memory and/or an external memory. The memory 10 may store commands or data related to at least one other component of the electronic device, for example. Additionally, the memory 10 may store software and/or programs. The program may comprise, for example, a kernel, middleware, an application programming interface (API), and/or an application program (or “application”). At least a portion of the kernel, middleware, or API may be referred to as an operating system.

The memory 10 stores instructions for performing an arc detection method to be described hereinafter.

Meanwhile, a non-transitory computer readable medium in which a program for sequentially performing an arc detection method according to some embodiments of the present disclosure is stored may be provided. A non-transitory computer-readable medium means a medium that stores data semi-permanently and may be read by a computer, not a medium that stores data for a short moment, such as registers, caches, and memory. More specifically, the aforementioned various applications or programs may be provided by being stored in a non-transitory readable medium such as a CD, DVD, hard disk, Blu-ray disk, USB, memory card, ROM, or the like. Examples of program instructions have not only machine language codes such as those produced by a compiler, but also high-level language codes that may be executed by a computer using an interpreter or the like. The hardware device described hereinafter may be configured to operate as one or more software modules to perform the operation of the present disclosure, and vice versa.

The processor 20 may comprise one or more of a central processing unit, an application processor, and a communication processor (CP). The processor 20 may perform calculation or data processing related to communication and/or control of at least one other component of a computing device or a non-transitory computer-readable medium, for example.

The display 30 may comprise, for example, a liquid crystal display (LCD), a light emitting diode (LED) display, an organic light emitting diode (OLED) display, or a microelectromechanical system (MEMS) display, or electronic paper display. The display 30 may display various types of content (For example, text, images, videos, icons, and/or symbols, etc.) to a user, for example. The display 30 may comprise a touch screen, and may receive, for example, a touch, gesture, proximity, or hovering input using an electronic pen or a part of the user's body.

The interface unit 40 allows the computing device to communicate with the outside through a network. The network herein comprises both wired and wireless systems. In particular, wireless communication, for example, may comprise cellular communication using at least one of LTE, LTE-A (LTE Advance), CDMA (code division multiple access), WCDMA (wideband CDMA), UMTS (universal mobile telecommunications system), WiBro (Wireless Broadband), or GSM (Global System for Mobile Communications) and the like. Alternatively, the wireless communication may comprise at least one of WiFi (wireless fidelity), LiFi (light fidelity), Bluetooth, Bluetooth low power (BLE), Zigbee, NFC (near field communication), magnetic secure transmission, radio frequency (RF), or a body area network (BAN) and the like. Alternatively, the wireless communication may comprise GNSS. The GNSS may be, for example, a Global Positioning System (GPS), a Global Navigation Satellite System (Glonass), a Beidou Navigation Satellite System (hereinafter “Beidou”), or Galileo, the European global satellite-based navigation system. The wired communication may comprise at least one of, for example, USB (universal serial bus), HDMI (high-definition multimedia interface), RS-232 (recommended standard232), power line communication, or POTS (plain old telephone service), computer network (e.g., LAN or WAN) and the like.

According to an embodiment of the present disclosure, the memory 10 may comprise a data collection unit 100 and an arc detection unit 200. The data collection unit 100 and the arc detection unit 200 are the same as those shown in FIG. 4, and a description thereof will be omitted.

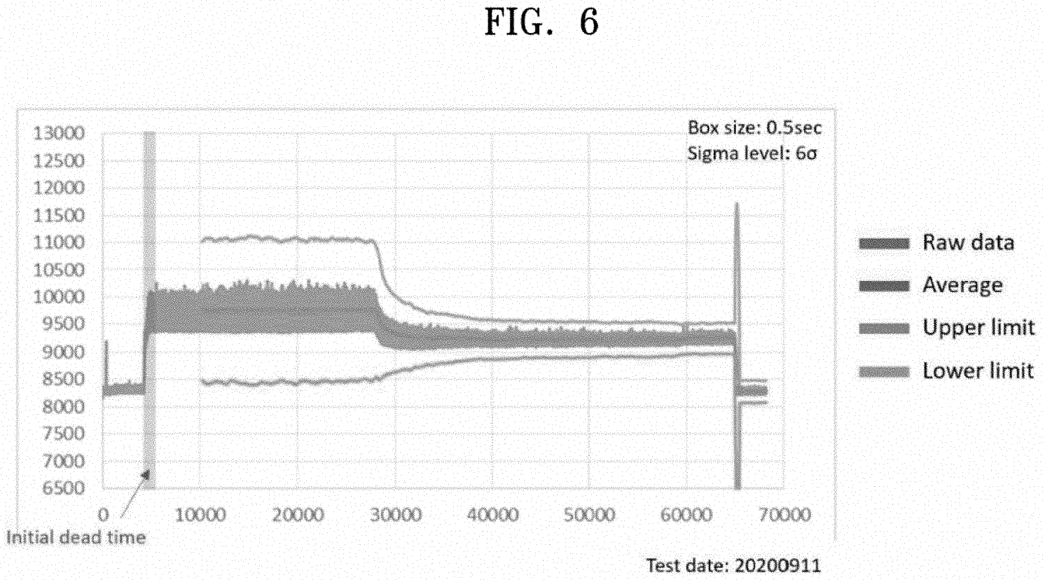

FIG. 6 is a view showing an embodiment of setting an upper limit and a lower limit for arc detection according to an embodiment of the present disclosure.

Referring to FIG. 6, a portion marked in blue indicates raw data collected by the data collection unit 100. In an embodiment, the data separation unit 210 may separate sections for each data having similar characteristics, and the calculation unit 220 may calculate an average value and a standard deviation of the data separated by the data separation unit 210. The reference setting unit 230 may set an upper limit and a lower limit using a value calculated by the calculation unit 220.

Referring to FIG. 6, the red line indicates the average value of the data. A reference point is set based on this by setting the value added by n times the standard deviation as the upper limit, and the value subtracted by n times the standard deviation as the lower limit. At this time, it can be seen that the upper limit is indicated by a gray line and the lower limit is indicated by a yellow line.

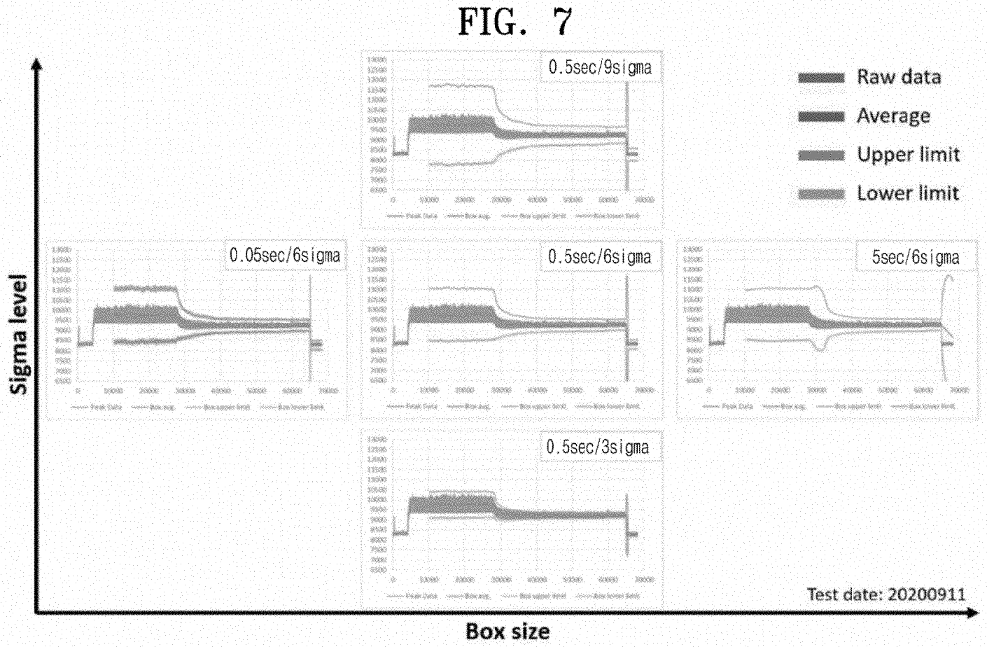

FIG. 7 is a diagram showing an embodiment of setting an upper limit and a lower limit under various conditions.

Referring to FIG. 7, embodiments of the case where the size of the box is set differently (horizontal axis) and the case where the multiple of the standard deviation is set differently (vertical axis) are shown.

According to the horizontal axis of FIG. 7, it can be seen that when the size of the box is set to be large, there is a smoothing effect of the overall data and the upper and lower limits, and when the size of the box is set to be small, it can be seen that the upper and lower limits are set more roughly.

According to the vertical axis of FIG. 7, it can be seen that when the multiples of the standard deviation are set differently, the range of the detectable arc is provided differently.

According to the present disclosure, the upper and lower limits are tracked in real time by adding or subtracting a multiple of the standard deviation to and from the average value of a specific period of raw data. When a peak value exceeds the upper and lower limits, it may be determined that arc has occurred. Referring to FIG. 7, the smoothness and size of the upper and lower limits may be adjusted according to the size of the period set by the data separation unit 210 and the multiple level of the standard deviation. The larger the box size is, the smoothing effect is, but there may be a delay in the process of collecting data to measure the average value.

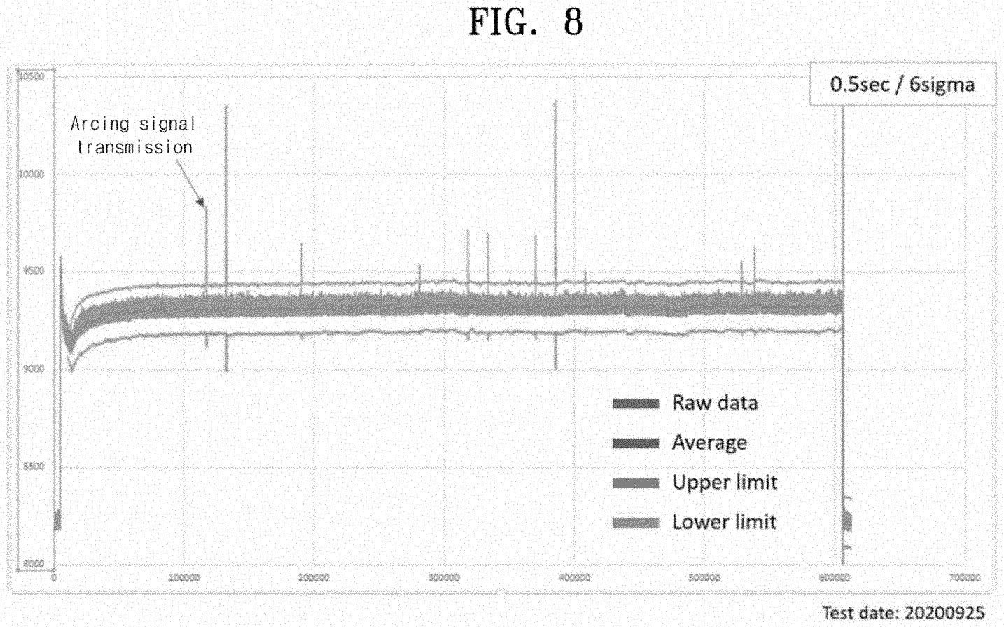

FIG. 8 is a view showing performing arc detection according to an embodiment of the present disclosure.

Referring to FIG. 8, when a peak exceeds the upper limit, it can be seen that an arcing signal has occurred.

FIG. 9 is a view for explaining section setting in data.

According to the present disclosure, the data separation unit 210 may set a dead time period in which an arc is not detected for several seconds immediately after the start of the process and just before the end of the process. The data separation unit 210 may collect data except for dead time and may set a box. The data separation unit 210 collects data except for the dead time, so that a sudden change in intensity, when plasma is turned on and off, may be ignored. Additionally, it is possible to ignore the initial unstable state in which the plasma was generated.

In the present disclosure, as the size of the period increases, the arc cannot be traced for a period of time as much as the size of the first box, but the log of the first few seconds is less reliable, so the initial dead time is set to a few seconds. There is an effect that can increase the accuracy of the data

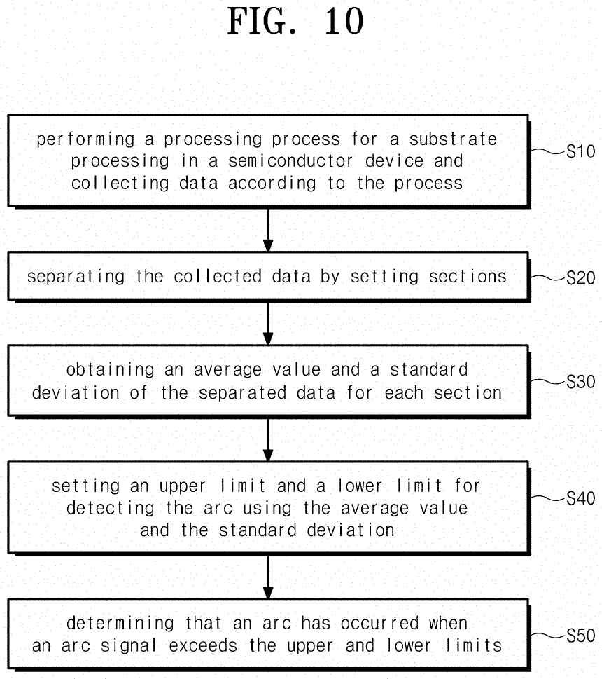

FIG. 10 is a view for describing an arc detection method according to an exemplary embodiment of the present disclosure.

The arc detection method according to the present disclosure may comprise the steps of: performing a processing process for a substrate processing in a semiconductor device and collecting data according to the process (S10); separating the collected data by setting sections (S20); obtaining an average value and a standard deviation of the separated data for each section (S30); setting an upper limit and a lower limit for detecting the arc using the average value and the standard deviation (S40); and determining that an arc has occurred when an arc signal exceeds the upper and lower limits (S50).

At this time, the separating the collected data by setting sections may separate the collected data except for the data immediately after the start of the process and immediately before the end of the process.

At this time, the setting an upper limit and a lower limit for the arc detection using the average value and the standard deviation may set an upper limit by adding n multiplied by any number of the standard deviation to the average value, and may set a lower limit by subtracting n times the standard deviation from the average value. Additionally, the setting an upper limit and a lower limit for the arc detection using the average value and the standard deviation may set the upper and lower limits differently for each parameter or recipe in the processing process.

The arc detection method according to the present disclosure is not limited to specific equipment and parameters such as CCP/ICP equipment, asher/etcher, Vrms/EPD intensity, and may detect arcs of various semiconductor device.

According to the present disclosure, noise can be ignored and the overall trend can be tracked in real time by setting a relatively large box and performing data processing on a relatively large box, rather than following a high-resolution parameter by a time interval through data sampling. The conventional arc detection method such as tracking only the slope value of a parameter in real time has disadvantages in that it does not keep up with the development speed of a high-resolution arc detector, so that the quality of data is degraded or that it cannot cope with various film qualities and process recipes. The present disclosure has advantages in that, by efficiently utilizing the average value and standard deviation multiple of the box set in real time, it reacts in real time to high-resolution arc detectors, ignores noise, and is independent of the absolute value of the parameter, absolute slope value and the number of points sensitively reacted by various film qualities and process recipes. Additionally, various applications are expected to be made for various equipment groups without being limited to an asher.

It should be understood that the embodiments herein are intended for helping understanding of the present disclosure, and are not intended to limit the scope of the present disclosure, and various modified embodiments are also within the scope of the present disclosure. Therefore, the technical protection scope of the present invention will be defined by the technical spirit of the appended claims. That is, the technical protection scope of the present invention should be construed to include modifications, equivalents, and substitutes of the components described in the above embodiments.
1: An arc detection system
10: A memory
20: A processor
30: An interface unit
40: A display
100: A data collection unit
200: An arc detection unit
210: A data separation unit
220: A calculation unit
230: A reference setting unit
240: A determination unit

What is claimed is:

1. A method of detecting an arc in a semiconductor device, the method comprising:
performing a processing process for a substrate processing and collecting data according to the processing process;
separating the collected data by setting sections;
obtaining an average value and a standard deviation of the data separated for each section; and
setting an upper limit and a lower limit for detecting the arc using the average value and the standard deviation.

2. The method of claim 1, wherein the separating the collected data by setting sections comprise separating the collected data except for data immediately after the start of the processing process and immediately before the end of the processing process.

3. The method of claim 1, wherein in the setting an upper limit and a lower limit for the arc detection using the average value and the standard deviation, the upper limit is set by adding n multiplied by any number of the standard deviation to the average value and the lower limit is set by subtracting n multiplied by any number of the standard deviation from the average value.

4. The method of claim 1, wherein the separating the collected data by setting sections comprises separating the collected data based on the number of data.

5. The method of claim 3, further comprising determining that an arc has occurred when a detected signal exceeds the upper and lower limits.

6. The method of claim 5, wherein the setting an upper limit and a lower limit for the arc detection using the average value and the standard deviation comprises setting the upper and lower limits differently for each parameter or recipe in the processing process.

7. A computer-readable recording medium storing a program for executing the method of claim 6.

8. A system capable of detecting an arc generated in a semiconductor device, the system comprising: a data collection unit for collecting a result of processing a substrate for processing a substrate; and an arc detection unit for detecting the arc using an average value and a standard deviation for each section based on the data collected by the data collection unit.

9. The system of claim 8, wherein the arc detection unit comprises:
a data separation unit for separating the data collected by the data collection unit for each section;
a calculation unit for calculating an average value and a standard deviation of the data separated for each section in the data separation unit;
a reference setting unit for setting an upper limit and a lower limit for arc detection by applying a value calculated by the calculation unit; and
a determination unit for determining that an arc has occurred when a detected signal exceeds the reference value set by the reference setting unit.

10. The system of claim 8, wherein the data separation unit separates the collected data except for data immediately after the start of the process and immediately before the end of the process.

11. The system of claim 8, wherein the reference setting unit sets the upper limit by adding n multiplied by any number of the standard deviation to the average value, and sets the lower limit by subtracting an n multiplied by any number of the standard deviation from the average value.

12. The system of claim 11, wherein the reference setting unit sets an upper limit and a lower limit differently for each parameter or recipe in the processing process.

13. An arc detection system comprising a processor and a memory storing program code executable by the processor, the processor executing:
performing a processing process for a substrate processing and collecting data according to the processing process;
separating the collected data by setting sections;
obtaining an average value and a standard deviation of the data separated for each section; and setting an upper limit and a lower limit for detecting an arc using the average value and the standard deviation.

14. The system of claim 13, wherein the processor separates the collected data except for data immediately after the start of the process and immediately before the end of the process.

15. The system of claim 13, wherein the processor sets the upper limit by adding n multiplied by any number of the standard deviation to the average value and sets the lower limit by subtracting n multiplied by any number of the standard deviation from the average value as the lower limit.

16. The system of claim 13, wherein the processor separates the collected data by setting sections based on the number of data.

17. The system of claim 15, wherein the processor determines that an arc has occurred when a detected signal exceeds the upper and lower limits.

18. The system of claim 17, wherein the processor sets the upper and lower limits differently for each parameter or recipe in the processing process.
